(19) United States
(12) Patent Application Publication
(10) Pub. No.: US 2017/0288604 A1
(43) Pub. Date: Oct. 5, 2017

(54) SOLAR PANEL DESIGN ASSEMBLY

(71) Applicant: Patrick Kenneth Powell, Farmington Hills, CT (US)

(72) Inventor: Patrick Kenneth Powell, Farmington Hills, CT (US)

(21) Appl. No.: 15/479,536

(22) Filed: Apr. 5, 2017

Related U.S. Application Data
(60) Provisional application No. 62/318,285, filed on Apr. 5, 2016.

(51) Int. Cl. H02S 20/30; H01L 31/0216; H01L 31/0475; H01L 31/0232

(52) U.S. Cl. CPC H02S 20/30; H01L 31/02325; H01L 31/02164; H01L 31/0475

(57) ABSTRACT

A solar panel assembly according to an example of the present disclosure includes a light-permeable panel, an opaque or solid region on the panel that at least partially blocks light from penetration through the panel, at least one solar array adjacent the panel, and at least one mirror situated such that at least some light permeating through the panel reflects off of the at least one mirror and onto the at least one solar array.

### CROSS-REFERENCE TO RELATED APPLICATIONS

This application claims priority to U.S. Provisional Patent Application Ser. No. 62/318,285, filed Apr. 5, 2016.

### BACKGROUND

Solar panels frequently include sizeable surface areas that are visible to the public. Typically solar panels require unobstructed access to light in order to generate electricity.

### SUMMARY

A solar panel assembly according to an example of the present disclosure includes a light-permeable panel, an opaque or solid region on the panel that at least partially blocks light from penetration through the panel, at least one solar array adjacent the panel, and at least one mirror situated such that at least some light permeating through the panel reflects off of the at least one mirror and onto the at least one solar array.

In a further embodiment of any of the foregoing embodiments, the at least one solar array is configured to convert light into usable energy.

In a further embodiment of any of the foregoing embodiments, the usable energy is electric current.

In a further embodiment of any of the foregoing embodiments, the at least one mirror is non-flat.

In a further embodiment of any of the foregoing embodiments, the at least one mirror has at least one of a convex and a concave region.

In a further embodiment of any of the foregoing embodiments, the opaque or solid regions form a design.

In a further embodiment of any of the foregoing embodiments, the at least one solar array is on a solar panel arranged behind a back side of the panel.

In a further embodiment of any of the foregoing embodiments, at least some light permeates through the panel directly to the at least one solar array.

In a further embodiment of any of the foregoing embodiments, the at least one mirror is arranged on the back side of the panel and is facing towards the solar panel.

In a further embodiment of any of the foregoing embodiments, the at least one mirror is laterally aligned with the opaque or solid region.

In a further embodiment of any of the foregoing embodiments, the opaque or solid region shields a portion of the solar panel, and the portion of the solar panel is free from the at least one solar array.

In a further embodiment of any of the foregoing embodiments, the at least one solar array is on a back side of the panel.

In a further embodiment of any of the foregoing embodiments, the at least one solar array is laterally aligned with the opaque or solid region.

In a further embodiment of any of the foregoing embodiments, the at least one mirror is arranged on a backing situated behind a back side of the panel and is facing towards the panel.

A solar energy collecting system according to an example of the present disclosure includes a solar panel assembly. The solar panel assembly has a light-permeable panel, an opaque or solid region on the panel that at least partially blocks light from penetration through the panel, at least one solar array adjacent the panel, and at least one mirror situated such that at least some light permeating through the light-permeable panel impinges off of the mirror and reflects onto the solar array, and a control system configured to control the solar panel assembly.

A further embodiment of any of the foregoing embodiments include a communications system configured to receive signals and communicate the signals to the control system.

A further embodiment of any of the foregoing embodiments include an energy storage device configured to store energy collected by the solar panel assembly.

A further embodiment of any of the foregoing embodiments include an actuator configured to move the solar panel assembly.

In a further embodiment of any of the foregoing embodiments, the actuator is controlled by the control system.

In a further embodiment of any of the foregoing embodiments, the actuator is controlled by the control system to move the solar panel assembly to maximize the amount of energy collected by the solar panel assembly.

### BRIEF DESCRIPTION OF THE DRAWINGS

FIG. 1A schematically illustrates a solar panel advertising assembly.

FIG. 1B schematically illustrates a side view of the solar panel design assembly of FIG. 1A.

FIG. 1C schematically illustrates a more detailed side view of the solar panel design assembly of FIG. 1A.

FIG. 2 schematically illustrates a solar panel.

FIG. 3A schematically illustrates a design panel.

FIG. 3B schematically illustrates a detail view of the design panel of FIG. 3A.

FIG. 3C schematically illustrates another detail side view of the design panel of FIG. 3A.

FIG. 4 schematically illustrates the solar panel design assembly of FIG. 1A with an observer.

FIG. 5 schematically illustrates a solar energy collecting system.

FIG. 6 schematically illustrates an alternate solar panel design assembly.

The various features and advantages of the present disclosure will become apparent to those skilled in the art from the following detailed description. The drawings that accompany the detailed description can be briefly described as follows.

### DETAILED DESCRIPTION

A typical solar panel includes an array of photovoltaic cells that require unobstructed access to light in order to generate electric current. Under such a paradigm, the use of a non-solar panel or other structure in front of the solar panel would only serve to reduce the efficiency and value of the solar panel. However, as will be described herein below, there is a specially designed panel that provides value to the system while minimizing efficiency loss.

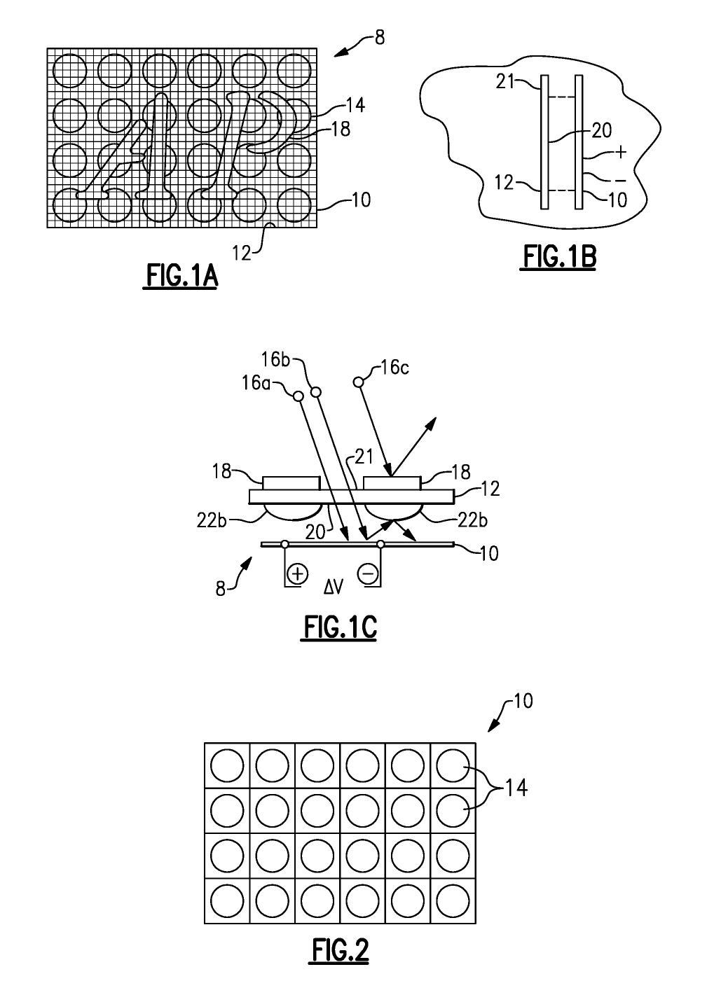

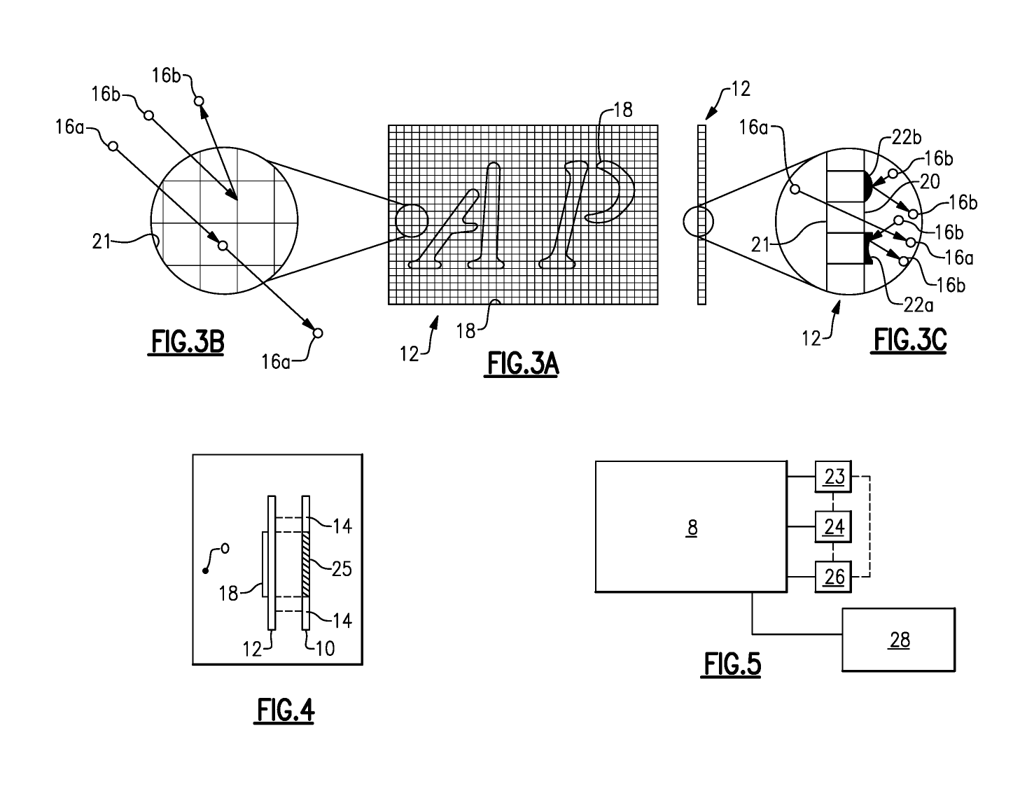

FIGS. 1A-C illustrate an example solar panel design assembly 8. The assembly 8 includes a solar panel 10 and a design or light-permeable panel 12 (hereafter “design panel 12”). The design panel 12 is arranged outward from the solar panel or array 10, i.e., the light-receiving functional side of the solar panel 10. In one example, the design panel 12 is spaced from the solar panel 10. The solar panel 10, shown in isolation in FIG. 2, includes a plurality of solar arrays 14. For example, the solar arrays 14 include one or more photovoltaic cells arranged in a pattern.

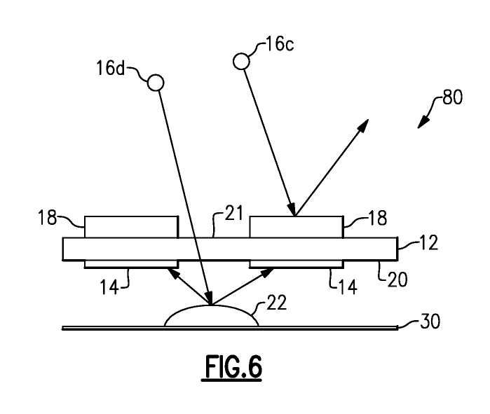

The design panel 12 is shown in detail in FIGS. 3A-3C. The design panel 12 is glass, in one example, but other light-permeable materials can be used in other examples. The design panel 12 has a front outward facing surface 21 (FIG. 1C) and a back inward facing surface 20 with respect to a light (photon) source, e.g., the sun. A portion 18 of the design panel 12 is opaque or solid. In one example, the opaque or solid portion 18 makes up a design, such as an advertisement. In the example shown, the design 18 comprises lettering. However, in other examples, the design 18 includes any type of artwork, pattern, or drawing in one or more colors.

Referring to FIG. 1C, light photons (generally “16”) permeate or travel through areas of the design panel 12 that are not covered by the design 18 and hit the surface of a solar panel 10. A portion of the photons, designated as 16a, are absorbed by the solar panel 10 into the solar array 14 and converted into usable energy such as electric current. Another portion of the photons, designated at 16b, are reflected off of the solar panel 10. A third portion of the photons, designated as 16c, are reflected off the design 18 on the design panel 12. When these photons 16c are perceived by an observer, the observer can see the design 18. Photons 16 can impinge on the design panel 12 straight on or at an angle with respect to the design panel 12.

In some examples, the design 18 is applied to the design panel 12 by painting, coating, or other deposition techniques such as chemical vapor deposition or sputtering. More particularly, the design 18 can be applied to the design panel 12 by sacrificial printing followed by vapor deposition of a pigment, paint, or coating. Then, the sacrifice can be washed out, leaving the design 18 behind. In another example, the design 18 is embedded into the material of the design panel.

Referring to FIG. 3C, at least a portion of an inward facing side 20 of the design panel 12 comprises a mirrored surface, generally 22. As shown in FIG. 3C, the mirrored surface 22 can be non-flat. For instance, the mirrored surface 22 can be concave (22a) or convex/dome-shaped (22b). The mirrored surface 22 reflects photons 16b back onto or toward the solar panel 10. This helps counteract loss of efficiency of the solar panel 10 due to the reflection of some photons 16c by the design panel 12 that do not reach the solar panel 10. Specifically, the mirrored surface 22 increases overall photon incidence on the solar panel 10 and increases the amount of photons that are absorbed into the solar array 14.

In the example of FIG. 1C, mirrored surface 22 is only present in areas of the design panel 12 that have portions of the design 18 on the opposite side. That is, the mirrored surface 22 is only located on the portions of the inward facing surface 20 of the design panel 12 that correspond to the portion of the outward facing surface 21 of the design panel 12 covered by the design 18. However, in other examples the mirrored surface 22 is present in other areas of the design panel 12.

In one example, illustrated in FIG. 4, the solar arrays 14 are only present in areas of the solar panel 10 not covered by the design 18 from the perspective of an observer (O) observing the solar panel design assembly 8 straight-on. That is, from the perspective of the observer (O), there is an area 25 of the solar panel 10 that is aligned with the design 18 with respect to an observer (O) to the assembly 8. Thus, the area 25 is shielded from some photons 16 by the design 18, and is free from solar arrays 14. Since photons 16 are blocked from reaching area 25 by the design 18, this arrangement reduces cost of the solar panel design assembly 8 without reducing its efficiency. Though the observer (O) is shown in FIG. 4 viewing the design panel 12 straight on, in other examples, the observer is positioned at an angle with respect to the design panel 12, changing the definition of the area 25. For instance, the solar panel design assembly 8 can be situation on the roof of a building, and the observer is located at ground level.

FIG. 5 shows an example solar energy collecting system. The system includes the solar panel design assembly 8, a communications system 23, a control system 24, an actuator 26, and an energy storage device 28. The communications system 23 receives signals, for example, from an operator, and communicates the signals to the control system 24. The control system 24 controls the actuator 26, which moves the solar panel design assembly 8. In one example, the control system 24 controls the actuator 26 in response to signals communicated from the communications system 23. For instance, signals cause the actuator 26 to position the solar panel design assembly 8 in such a way as to maximize photon absorption and thus energy conversion. Finally, energy collected by the solar panel design assembly 8 is stored in energy storage device 28.

FIG. 6 shows an alternate solar panel design assembly 80. In this example, the design 18 is on an outward side 21 of the design panel 12, while solar arrays 14 are on the inward side 20 of the design panel 12. A backing 30 is arranged inward of the design panel 12. Photons 16d travel through the design panel 12 in areas of the design panel 12 not covered by the design 18, as described above. At least part of the backing 30 is a mirrored surface 22 to reflect these photons 16d towards the solar arrays 14. Other photons 16c reflect off of the design 18, as described above. Though the example of FIG. 6 shows the mirrored surface 22 as dome-shaped/convex, concave or angled surfaces can be used instead of or in addition to dome-shaped/convex surfaces.

In the example of FIG. 6, solar arrays 14 are only present in areas of the design panel 12 that have portions of the design 18 on the opposite side. That is, the solar arrays 14 are only located on the portions of the inward facing surface 20 of the design panel 12 that correspond to portions of the outward facing surface 21 of the design panel 12 covered by the design 18. Said another way, the design 18 and solar arrays 14 are aligned with respect to an observer (O) to the assembly 80 as shown in FIG. 4. However, in other examples solar arrays 14 are present in other areas of the design panel 12.

Although a combination of features is shown in the illustrated examples, not all of them need to be combined to realize the benefits of various embodiments of this disclosure. In other words, a system designed according to an embodiment of this disclosure will not necessarily include all of the features shown in any one of the figures or all of the portions schematically shown in the figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from this disclosure. The scope of legal protection given to this disclosure can only be determined by studying the following claims.

What is claimed is:

1. A solar panel assembly comprising:
a light-permeable panel;
an opaque or solid region on the panel that at least partially blocks light from penetration through the panel;
at least one solar array adjacent the panel; and
at least one mirror situated such that at least some light permeating through the panel reflects off of the at least one mirror and onto the at least one solar array.

2. The solar panel assembly of claim 1, wherein the at least one solar array is configured to convert light into usable energy.

3. The solar panel assembly of claim 2, wherein the usable energy is electric current.

4. The solar panel assembly of claim 1, wherein the at least one mirror is non-flat.

5. The solar panel assembly of claim 1, wherein the at least one mirror has at least one of a convex and a concave region.

6. The solar panel assembly of claim 1, wherein the opaque or solid regions form a design.

7. The solar panel assembly of claim 1, wherein the at least one solar array is on a solar panel arranged behind a back side of the panel.

8. The solar panel assembly of claim 7, wherein at least some light permeates through the panel directly to the at least one solar array.

9. The solar panel assembly of claim 7, wherein the at least one mirror is arranged on the back side of the panel and is facing towards the solar panel.

10. The solar panel assembly of claim 9, wherein the at least one mirror is laterally aligned with the opaque or solid region.

11. The solar panel assembly of claim 7, wherein the opaque or solid region shields a portion of the solar panel, and the portion of the solar panel is free from the at least one solar array.

12. The solar panel assembly of claim 1, wherein the at least one solar array is on a back side of the panel.

13. The solar panel assembly of claim 12, wherein the at least one solar array is laterally aligned with the opaque or solid region.

14. The solar panel of claim 12, wherein the at least one mirror is arranged on a backing situated behind a back side of the panel and is facing towards the panel.

15. A solar energy collecting system comprising:
a solar panel assembly, the solar panel assembly including a light-permeable panel, an opaque or solid region on the panel that at least partially blocks light from penetration through the panel, at least one solar array adjacent the panel, and at least one mirror situated such that at least some light permeating through the light-permeable panel impinges off of the mirror and reflects onto the solar array; and
a control system configured to control the solar panel assembly.

16. The solar energy collecting system of claim 15, further comprising a communications system configured to receive signals and communicate the signals to the control system.

17. The solar energy collecting system of claim 15, further comprising an energy storage device configured to store energy collected by the solar panel assembly.

18. The solar energy collecting system of claim 15, further comprising an actuator configured to move the solar panel assembly.

19. The solar energy collecting system of claim 18, wherein the actuator is controlled by the control system.

20. The solar energy collecting system of claim 19, wherein the actuator is controlled by the control system to move the solar panel assembly to maximize the amount of energy collected by the solar panel assembly.
